(19) United States
(12) Patent Application Publication
(10) Pub. No.: US 2019/0329285 A1
(43) Pub. Date: Oct. 31, 2019

(54) APPARATUS AND METHOD FOR DEVELOPING FINGERPRINTS AT COOL TEMPERATURES

(71) Applicant: AIR SCIENCE USA LLC, Fort Myers, FL (US)

(72) Inventor: Paul CHAMBRE, Fort Myers, FL (US)

(73) Assignee: AIR SCIENCE USA LLC, Fort Myers, FL (US)

(21) Appl. No.: 15/964,930

(22) Filed: Apr. 27, 2018

(51) Int. Cl. B05D 1/00; C23C 14/12

(52) U.S. Cl. CPC B05D 1/60; C23C 14/12

(57) ABSTRACT

Method for detecting fingerprints comprising: providing a chamber 1 suitable for containing a substrate 2 suspected of containing a fingerprint; bringing the temperature of the chamber to a target temperature below ambient temperature utilizing a refrigeration unit 3 operatively associated with the chamber; placing the substrate suspected of containing a fingerprint in a suitable location 4 within the chamber and maintaining the substrate therein for a time sufficient to allow the substrate to attain the target temperature; bringing the humidity within the chamber to a target humidity utilizing a nebulizer/humidifier 5 operatively associated with the chamber and employing circulation fan 14 to ensure uniform temperature, humidity and vapor content throughout the chamber; providing a cyanoacrylate powder 6 in the chamber and raising the temperature of the cyanoacrylate powder to a temperature which vaporizes the cyanoacrylate powder utilizing a cyanoacrylate accelerator 7 operatively associated with the chamber. This procedure develops any fingerprints present on the substrate. Subsequently, venting system 12 purges the fumes and then the substrate is removed from the chamber and inspected to visualize any cyanoacrylate-coated fingerprints present.

### FIELD OF THE INVENTION

This invention relates to the detection of fingerprints. More specifically, this invention relates to a method of, and to an apparatus for, fingerprint development—using a solid form of polycyanoacrylate that is vaporized and then employed to coat a substrate which may contain a fingerprint. The inventive method employs cool temperatures to enhance the sensitivity and/or accuracy of fingerprint detection.

### BACKGROUND OF THE INVENTION

Fingerprint powders are fine powders used in dusting for fingerprints. The process of dusting for fingerprints involves various methods intended to get the particles of the powder to adhere to residue left by friction ridge skin on the fingers. Fingerprints often leave residues of oils in the shape of the friction ridges, but the friction ridge skin itself does not secrete oils. For this reason, some fingerprints will only leave a residue of amino acids and other compounds to which the powder does not adhere.

Powders may be applied with a fingerprint brush, which is a brush with extremely fine fibers designed to hold powder and deposit it gently on the fingerprint to be revealed without rubbing away the often delicate residue of the fingerprint itself. Powders may also be applied by blowing the powder across the fingerprint, or by pouring the powder onto the print, and then blowing away the excess. Historically, lycopodium powder—that is, spores of mosses, ground cedar, and the like—was used as a fingerprint powder. Modern fingerprint powders have a variety of compositions, including for example aluminum powder, aluminum flakes, and lampblack. Factors influencing the effectiveness of fingerprint powders include fineness (the powder must be fine enough to show the detail of the fingerprint), adhesion (the powder should adhere to the residue of the fingerprint and not adhere to the rest of the surface so as to obscure the view of the print), color (the fingerprint powder should be a suitable color for the surface in question), and flowability (the powder should not cake into a solid).

Some surfaces do not lend themselves to the use of conventional fingerprint powders, so that use of alternate methods is necessary. Other media, such as certain types of glue, can be “smoked” over these surfaces to develop the latent fingerprints thereupon. For instance, when the specimen is a metallic weapon such as a handgun or a knife, synthetic leather, or an adhesive face of an adhesive tape, dusting with powder cannot copy the fingerprint clearly. Instead, methods in which 2-cyanoacrylate is vaporized and converted via moisture on a fingerprint to a polymer have been used as a method for developing a fingerprint residue more clearly. Conventionally, such fingerprint detection has been conducted with what is, in effect, liquid cyanoacrylate glue.

The detection of fingerprint using cyanoacrylate material is carried out by means of allowing a vapor of cyanoacrylate (monomer) to adhere to a fingerprint. For instance, cyanoacrylate (monomer) may be sprayed onto latent fingerprints or impregnated into woven or nonwoven fabric and allowed to volatilize onto the latent fingerprints. Another known method involves simultaneous use of vapors of cyanoacrylate (monomer) and a sublimation dye, to colorize the fingerprint detection when the fingerprints are present on a white or silvery colored metallic surface. U.S. Pat. No. 9,750,436 (Chambre) describes processes for detecting latent fingerprints using particularly advantageous forms of cyanoacrylate powders.

Various apparatuses have been developed for developing fingerprints. For instance, U.S. Pat. No. 6,660,054 (Manna) discloses an apparatus in which the improvement is containment and adsorption of fumes. U.S. Pat. No. 8,272,343 (Weaver) discloses a thermo-cycling apparatus that comprises heating coils and/or cooling coils adjacent to the fingerprint development chamber and that also comprises “a humidifying apparatus.” Weaver teaches in lines 1-2 of column 12 that the “humidifying apparatus . . . includes a steam generator.” Weaver also teaches “thermo cycling,” which is to be repeated for from 2 to 9 cycles, in lines 26-38 of column 12. The “thermo cycling” involves lowering the temperature “to about freezing temperature (31° -33° F.) and then raising the temperature to about near body temperature (98° F.) in a low humidity environment.” U.S. Pat. No. 8,430,054 (Hunter) discloses a portable apparatus with facilities for heating the fingerprint development material as well as exhaust facilities for cleaning out the air within the chamber after use. U.S. Pat. No. 9,027,259 (Stones) discloses an apparatus for developing latent fingerprint on an object, wherein the apparatus comprises: a cooler operable to chill the object; a humidifier “operable to condense a thin uniform coating of water over all exposed surfaces of such chilled object bearing such latent fingerprint and over such latent fingerprint;” and a vacuum chamber “automatically controlled to be sufficient to remove said thin uniform coating of water from such object and to entirely remove such water from such latent fingerprint.” An innovative automatic apparatus for developing fingerprints is available as Safefume™ from Air Science USA of Fort Myers, Fla.

### SUMMARY OF THE INVENTION

In standard cyanoacrylate fuming practices, vapors of cyanoacrylate combine with fingerprint residues and polymerize to form a hard, whitish deposit. When the latent prints have been present on the substrate for a long period of time, successfully rehydrating and fuming the prints can be difficult. In all cases, moreover, if environmental conditions are not accurately controlled, too much cyanoacrylate may polymerize on the print, making analysis difficult.

Applicant's invention eliminates over-fuming and successfully rehydrates older prints by establishing an optimum temperature range inside of the fuming unit. According to the invention, moreover, higher relative humidity is established in the fuming chamber, which provides clearer, more accurate later prints from a variety of surfaces, such as those on polished firearms, bottles, and even plastic bags.

No vacuum chamber or inducement of vacuum is necessary with the present invention. Likewise, no steam generator and/or thermo-cycling is necessary with the present invention. Although a vacuum chamber or inducement of vacuum can be employed, it is not necessary for efficient operation. Likewise, although a steam generator and/or thermo-cycling may be employed, neither is necessary for efficient operation.

The present invention provides an improved method for detecting latent fingerprints. The inventive method makes use of an apparatus that includes a chamber suitable for containing a substrate suspected of containing a fingerprint. The apparatus comprises: a fuming chamber; a refrigeration/temperature control unit configured to provide a target temperature to the atmosphere within the fuming chamber; a water nebulizer/humidifier configured to provide a target humidity to the atmosphere within the fuming chamber; and a heat source configured to vaporize cyanoacrylate material (powder) located within the fuming chamber.

The inventive method comprises: providing a chamber suitable for containing a substrate suspected of containing a fingerprint; bringing the temperature of the chamber to a target temperature below ambient temperature (ambient temperature generally being 68-77° F., 20-25° C.) utilizing a refrigeration unit operatively associated with the chamber; placing the substrate suspected of containing a fingerprint in a suitable location within the chamber and maintaining the substrate therein for a time sufficient to allow the substrate to attain the target temperature; bringing the humidity within the chamber to a target humidity utilizing a nebulizer/humidifier operatively associated with the chamber; providing a cyanoacrylate powder in the chamber and raising the temperature of the cyanoacrylate powder to a temperature which vaporizes the cyanoacrylate utilizing a cyanoacrylate accelerator operatively associated with the chamber. This procedure develops any fingerprints present on the substrate. Subsequently, the substrate is removed from the chamber and inspected to visualize any cyanoacrylate-coated fingerprints present.

Specific embodiments of the present invention include the following features, numbered 1-14:

Feature 1: An apparatus for use in detecting fingerprints, said apparatus comprising: a chamber suitable for containing a substrate suspected of containing a fingerprint; a refrigeration unit operatively associated with the chamber; a nebulizer/humidifier operatively associated with the chamber; a location within the chamber for receiving the substrate, including a support for a substrate to be tested; a cyanoacrylate accelerator operatively associated with the chamber, wherein said cyanoacrylate accelerator is capable of heating cyanoacrylate material in the chamber; and a venting system to purge the atmosphere from the chamber after use, wherein said apparatus does not include heating coils for heating air in or supplied to the chamber or a steam generator for proving moisture in the chamber.

Feature 2. The apparatus of feature 1, wherein the chamber ranges in size from 2 feet in height to 2 feet in width to 2 feet in depth to 6 feet in height to 3 feet in depth to 8 feet in width.

Feature 3. The apparatus of feature 1, wherein the refrigeration unit is operatively connected with the interior of the chamber via at least one duct and at least one circulation fan.

Feature 4. The apparatus of feature 1, wherein a humidifier is located inside of the fingerprint detection chamber.

Feature 5. The apparatus of feature 1, wherein the chamber is provided with a foldable shelf and/or with one or more with removable hanging rods.

Feature 6. The apparatus of feature 1, wherein the cyanoacrylate accelerator is a hotplate.

Feature 7. A method for detecting fingerprints, said method comprising: providing an apparatus according to feature 1; setting the temperature of the chamber in said apparatus to a target temperature in the range 1-5° C.; placing the substrate suspected of containing a fingerprint in the chamber and maintaining the substrate therein for a period of time sufficient to allow the substrate to reach the target temperature; bringing the humidity within the chamber to a target humidity in the range 75-85% humidity; providing a cyanoacrylate material in the chamber; and subsequently raising the temperature of the cyanoacrylate material to a temperature which vaporizes the cyanoacrylate material and maintaining a vaporization temperature for 5-45 minutes; then removing the substrate from the chamber and inspecting the substrate to visualize cyanoacrylate-coated fingerprints if present on the substrate.

Feature 8. The method of feature 7, wherein said chamber comprises a refrigeration unit operatively connected with the interior of the chamber via a duct, and wherein said apparatus comprises at least one circulation fan to circulate cold air provided by said refrigeration unit.

Feature 9. The method of feature 7, wherein said chamber comprises a humidifier located inside of the chamber, a foldable shelf and removable hanging rods for supporting a substrate suspected of containing a fingerprint, and a hotplate.

Feature 10. The method of feature 7, wherein the temperature of the chamber in said apparatus is set to a target temperature of 2-4° C.

Feature 11. The method of feature 7, wherein bringing the humidity within the chamber is brought to a target humidity of 80% and the substrate suspected of containing a fingerprint is maintained in the chamber for from 15 to 30 minutes.

Feature 12. The method of feature 7, wherein the cyanoacrylate material is a powder and the temperature of the cyanoacrylate powder is raised to 220-230° C. and the cyanoacrylate powder is maintained at that temperature for from 15 to 30 minutes.

Feature 13. The method of claim 7, further comprising the step of purging the vapors from the interior of the chamber prior to inspecting the substrate to visualize cyanoacrylate-coated fingerprints if present on the substrate.

Feature 14. The method of feature 13, wherein said purging is conducted by exhaust fans which pass the fumes in the interior of the chamber through a filtration unit prior to discharging said fumes into the atmosphere.

### BRIEF DESCRIPTION OF THE DRAWINGS

FIG. 1 is a schematic side view illustrating some features of the inventive apparatus.

FIG. 2A is a perspective view of an apparatus according to the present invention.

FIG. 2B is a side view of the interior of the apparatus illustrated in FIG. 2A.

FIG. 2C is a front view of the exterior of the apparatus illustrated in FIG. 2A.

FIG. 2D is a top view of certain features present in the interior of the apparatus illustrated in FIG. 2A.

FIG. 3A schematically illustrates airflow into the chamber during initial stages of processing.

FIG. 3B schematically illustrates airflow in the chamber during processing of the cyanoacrylate powder.

FIG. 3C schematically illustrates airflow out of the chamber during post-processing venting.

FIG. 4 is a flowchart outlining the inventive process.

### DETAILED DESCRIPTION OF THE INVENTION

### The Apparatus

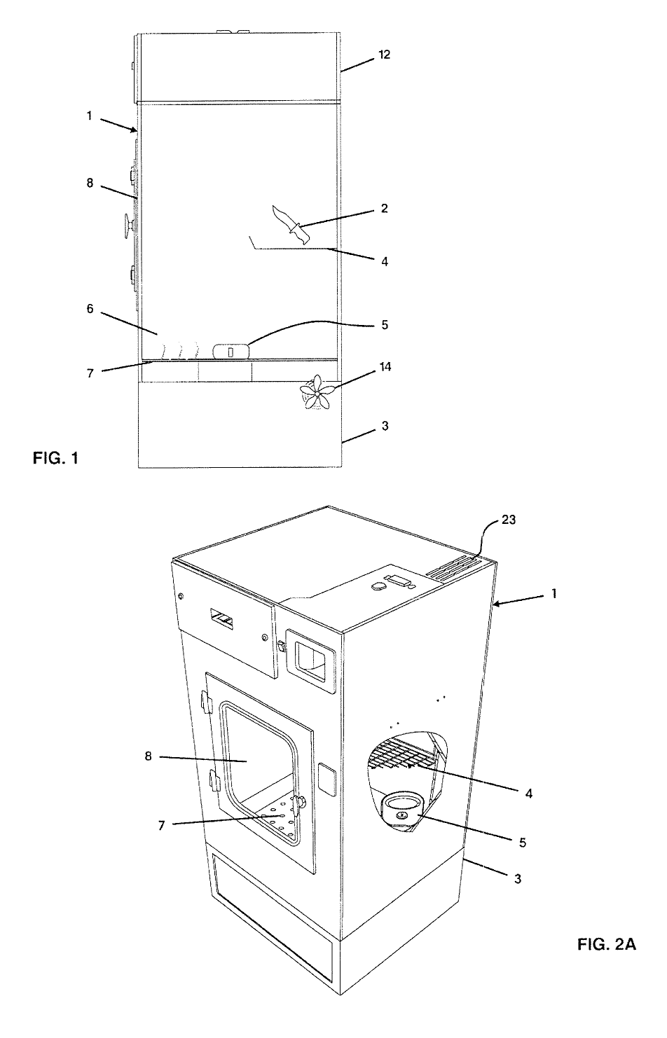

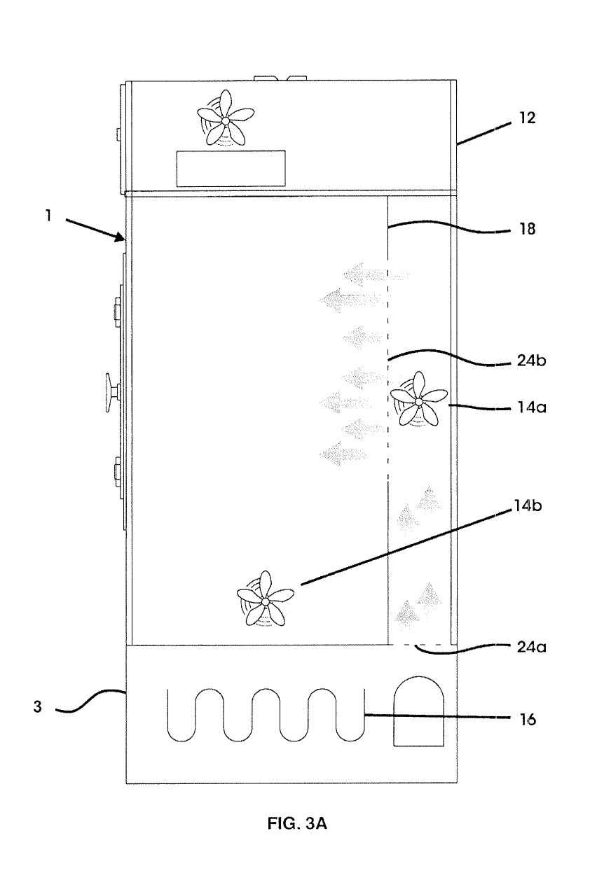

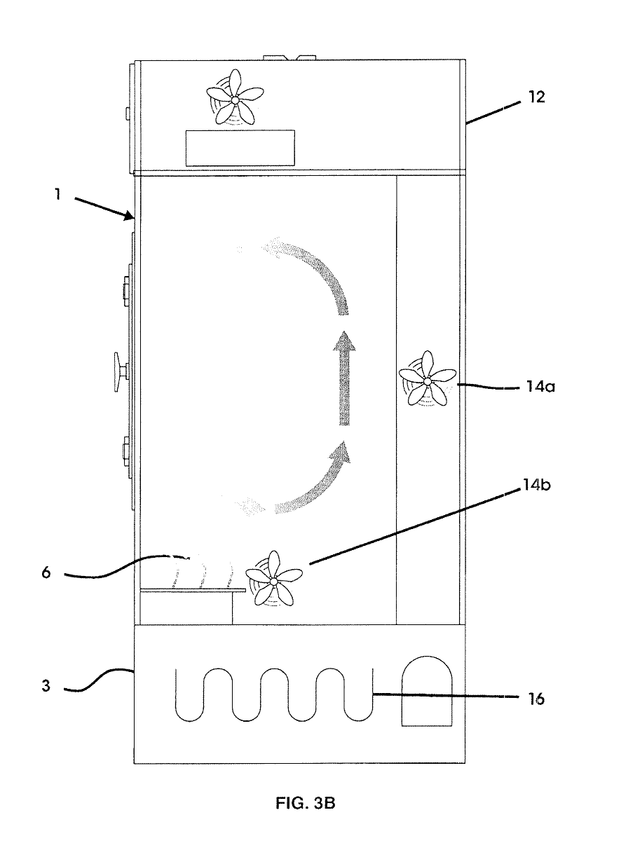

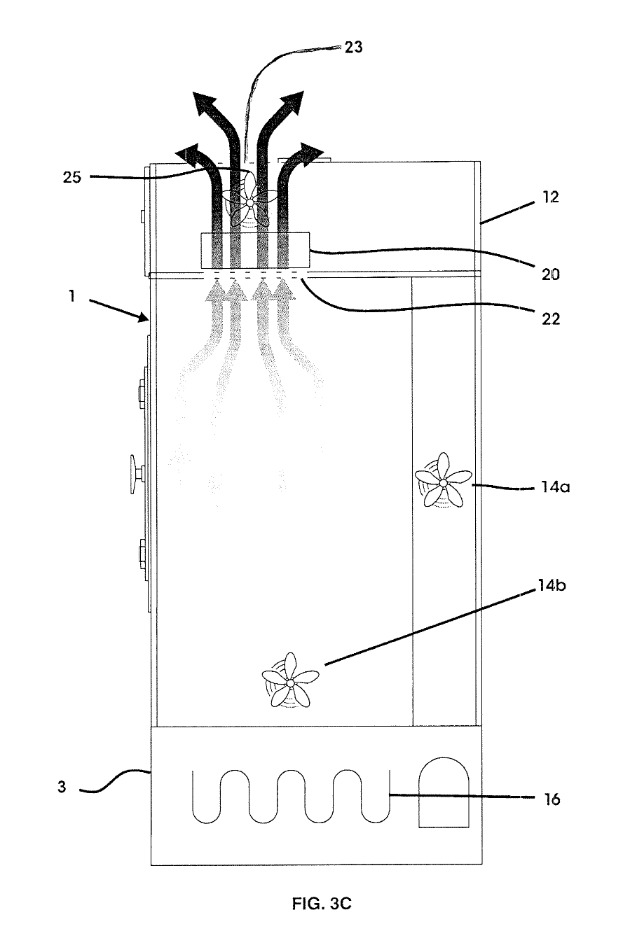

FIG. 1 is a schematic side view of an apparatus according to the present invention. The inventive apparatus includes: a chamber 1 suitable for containing a substrate 2 (such as a knife) suspected of containing a fingerprint; a refrigeration unit 3 operatively associated with the chamber; a suitable location, which may be a shelf 4, support or other mechanism for holding, suspending, or supporting a substrate positioned within the chamber; a nebulizer/humidifier 5 operatively associated with the chamber; and a cyanoacrylate accelerator 7 (such as a hotplate), within or operatively associated with the chamber, that vaporizes the cyanoacrylate material 6. Note: in FIG. 1 and in FIG. 3B, the cyanoacrylate material 6 is depicted as being vaporized.

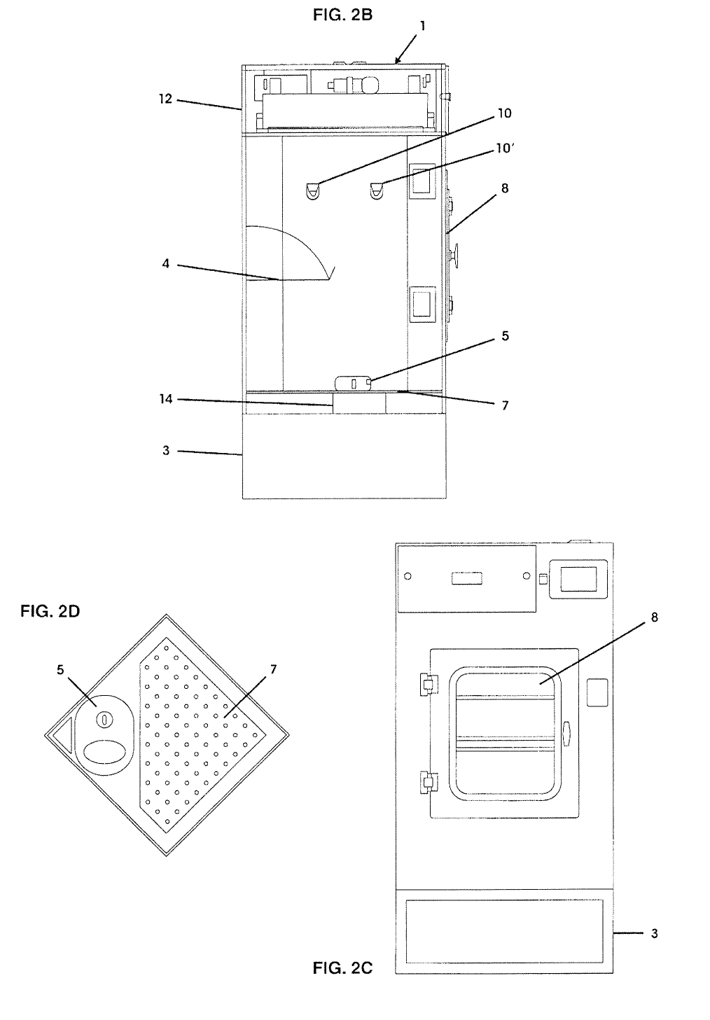

As explained in more detail below, refrigeration unit 3 may comprise cooling coils and condensors, and is operatively connected with the interior of the chamber via ducts or similar structural elements and one or more circulation fans, which enables refrigeration unit 3 to deliver cooled air to the interior of the apparatus. Fan icon 14 in FIG. 1 is representative of the cooled air delivery system. Fan icon 14 is not necessarily indicative of the location and/or orientation of a specific fan within the apparatus. Vent 23 in FIG. 1 is discussed in connection with FIG. 3C below. The inventive apparatus will also typically be provided with a viewing port 8 and a purge (vent) unit 12. FIG. 2A is a perspective view of an apparatus according to the present invention. FIG. 2C is a front view of the exterior of the apparatus illustrated in FIG. 2A.

The chamber 1 in the inventive apparatus may be in the form of a metal box approximately 4 feet in height with a width and a depth of approximately 2 feet each. Persons skilled in the art will understand, however, that other dimensions, both larger and smaller, will be operable. For instance, units as large as 6 feet in height by 3 feet in depth by 8 feet in width could be used when the latent fingerprints are on a large object (e.g., a motorcycle). Also, units as small as 2 feet by 2 feet by 2 feet could be used as portable devices.

The chamber box will be fitted with such conventional facilities as a power inlet, an on/off switch, a fan for circulating the atmosphere within the chamber, filters, an exhaust fan and exhaust port, internal lighting, and other such conventional features. As explained in connection with the fingerprint development method disclosed herein, processing involves the employment of a filtration unit (air scrubber) 12 operatively associated with chamber 1. The chamber box may be fitted with a viewing port 8, typically in the form of a metal door comprising tempered glass. The chamber box will be fitted with at least one fan 14a and/or 14b for circulating humidity, temperature, and glue (cyanoacrylate) vapors uniformly throughout the chamber; more than one such fan will typically be used to implement expedite the generation of a uniform atmosphere throughout the interior of the chamber. Fan icons 14a and 14b are not necessarily indicative of the location and/or orientation of specific fans within the apparatus.

As illustrated in FIG. 3A, the internal circulation system (represented in part by fan icon 14a) takes air from cooling coils 16 via perforations 24a and directs the cooled air through perforations 24b in wall 18 into the interior of chamber 1. Then, as illustrated in FIG. 3B, the internal circulation system (represented in part by fan icon 14b) circulates the cooled air within the interior of chamber 1. Thus, airflow into the chamber during initial stages of processing is illustrated schematically in FIG. 3A, while FIG. 3B schematically illustrates airflow within the chamber during processing of the cyanoacrylate powder.

The chamber box will also be fitted with a venting system 12, including a purge fan 25 and an air filter (e.g., a carbon filter) 20 to remove glue (cyanoacrylate) vapors from the chamber before the operator opens the door to remove the test substrate from the chamber, thereby avoiding or reducing operator exposure to noxious fumes. Fan icon 25 is not necessarily indicative of the location and/or orientation of a specific fan within the apparatus. Fan icon 25 represents a fan or fans that pull the air (containing noxious fumes) out of the chamber. Fan icon 14b represents a fan or fans that can assist emptying the chamber by pushing the air out of the chamber. Airflow out of the chamber during the post-processing venting operation is illustrated schematically in FIG. 3C. Ducts, typically equipped with valves or similar structural elements to ensure that fumes do not re-enter the chamber, are schematically represented by dashed lines 22 in FIG. 3C. Filtered air exits to the atmosphere through vent 23.

One feature of the interior of the chamber box is a suitable location within the chamber for receiving the substrate suspected of bearing fingerprints. The substrate 2 is illustrated in FIG. 1 as a knife. However, persons skilled in the art will understand that any substrate having suitable dimensions could be treated in the inventive apparatus. As illustrated in FIG. 2B, the suitable location may comprise a shelf 4, which would typically be a shelf comprising perforations (e.g., a metal mesh), in order to allow cyanoacrylate vapors to contact as much of the substrate as possible. Alternatively, one or more hanging rods could be used to hold the object at a suitable location. Reference characters 10 and 10′ in FIG. 2B indicate side view of hanging rods. The shelf may be configured to fold up against an inside wall of the chamber, or may be configured to be removable. The hanging rod(s) may be configured to be removable.

Another feature of the inventive apparatus is a refrigeration unit 3, which will be operatively associated with the chamber 1. In FIG. 1, the refrigeration unit 3 is depicted as being mounted at the bottom of the unit. However, persons of ordinary skill in the art will understand that the refrigeration unit may alternatively be mounted at the top or side of the unit. The refrigeration unit must be capable of cooling the temperature of the atmosphere inside of the chamber. Typically, the refrigeration unit will comprise cooling coils and condensors, similar to those in a conventional refrigerator such as those used to cool food. In order to cool the temperature of the atmosphere inside of the chamber, the refrigeration unit must be operatively connected with the interior of the chamber via ducts or similar structural elements (e.g., pipes, conduits, tubes, canals) and one or more circulation fans, which enables it to deliver cooled air to the interior of the apparatus. This operative connection is schematically represented by the elements having dashed lines 24a and 24b in FIG. 3A.

Yet another feature of the inventive apparatus is a nebulizer/humidifier 5, which will be operatively associated with the chamber. FIG. 2D includes a top view of a nebulizer/humidifier present in the interior of the apparatus illustrated in FIG. 2A. The function of the nebulizer/humidifier is to provide the atmosphere inside of chamber 1 with a desired level of humidity. A humidifier provides humidity by evaporating water. A nebulizer provides humidity by creating and spraying a fine mist of water droplets. In FIG. 1, the nebulizer/humidifier 5 is illustrated as being located inside of chamber 1. However, for instance in the case of a small chamber which does not have an internal volume sufficiently large to accommodate a nebulizer/humidifier, the nebulizer/humidifier could be mounted outside of the chamber box and be operatively connected therewith via pipes or similar structural elements and fans, in order to deliver water vapor to the interior of the apparatus in order to a desired level of humidity, details of which are discussed elsewhere in this application.

The inventive apparatus also comprises a cyanoacrylate accelerator 7 that is operatively associated with the chamber. The function of the “cyanoacrylate accelerator” is to heat the cyanoacrylate polymer so as to generate gases (vapors) of cyanoacrylate. Persons skilled in the art will understand that the cyanoacrylate accelerator may be a hotplate or another device capable of generating heat or flames. However, the cyanoacrylate accelerator is typically a hotplate. FIG. 2D includes a top view of a hotplate embodiment of a cyanoacrylate accelerator present in the interior of the apparatus illustrated in FIG. 2A. The cyanoacrylate accelerator 7 (hotplate) will typically be capable of providing a temperature in the range of 100 to 230° C. or to 240° C. A container to hold the cyanoacrylate material is typically placed on the hotplate.

### The Method

The inventive method includes bringing the temperature of the chamber to a target temperature range, e.g., 35-40° F. (2-4° C.). Slightly higher or lower temperatures could be used. However, if the temperature used is too low, freezing may occur, which would interfere with the fingerprint detection process. If the temperature used is too high, on the other hand (i.e., not cold enough), the benefits of the present invention will not be obtained. Subsequent to setting the temperature of the chamber to the target temperature range, the substrate suspected of containing a fingerprint is placed into the chamber and maintained therein for a period of time sufficient to allow the substrate to reach the target temperature. Meanwhile, or previously, the humidity within the chamber is brought to a target humidity (for instance, 80% humidity). Before further processing, the suspect substrate is maintained at that temperature and humidity for an amount of time sufficient to raise the substrate to the target temperature and humidity level, e.g., for 15-30 minutes. Shorter time periods may be appropriate with small substrates suspected of containing a fingerprint (e.g., a plastic ball point pen), while with especially large substrates (e.g., a motorcycle), a lengthier period may be necessary.

A cyanoacrylate material (powder), such as that described in U.S. Pat. No. 9,750,436 (Chambre), is placed into the chamber. A powdered polycyanoacrylate polymer having a particle diameter in the range of from 1 to 200 microns, with a median particle diameter of 10-30 microns and a mean particle diameter of approximately 30-90 microns, is suitable. An example of such a cyanoacrylate material is sold as CyanoPowder® by Air Science USA of Fort Myers, Fla. Alternatively, however, any conventional cyanoacrylate fingerprint powder may be used. If desired, liquid cyanoacrylate fingerprint development material could alternatively be utilized.

The fingerprint development method includes a heating step to heat the cyanoacrylate polymer so as to generate cyanoacrylate vapors. The cyanoacrylate polymer is depolymerized by heating, thereby generating the cyanoacrylate vapor. The heating in the heating step can be carried out by a hotplate or by another device that generates radiant heat or by flames. A hotplate is preferred. At this point, the temperature of the cyanoacrylate material which is present in the chamber is raised, for instant, by a hotplate present in the chamber, to a temperature which vaporizes the cyanoacrylate material (e.g., 212-464° F. (100-240° C.)). Where the cyanoacrylate fingerprint development material is a powder, a temperature of 220-230° C. would typically be used. Where the cyanoacrylate fingerprint development material is a liquid, a temperature of 100-140° C. would typically be used. The temperature of the cyanoacrylate material present in the chamber is maintained at that temperature for a suitable amount of time, e.g., for 15-30 minutes. Longer or shorter times may be employed, depending upon various factors such as the amount of cyanoacrylate powder or liquid relative to the size of the substrate being tested and the complexity of the surface of the substrate. The amount of the cyanoacrylate fingerprint development material which is utilized will typically be approximately 1 gram per cubic foot of volume in the chamber. Larger or smaller relative amounts may be employed, depending upon various factors such as the amount of cyanoacrylate material relative to the size of the substrate being tested and the complexity of the surface of the substrate.

Preferably, prior to opening the chamber and inspecting the suspect substrate, vapors are purged from the interior of the chamber. This purging step may be conducted by exhaust fans which pass the fumes in the interior of the chamber through a filtration unit prior to discharging the fumes into the atmosphere.

Finally, the substrate is removed from the chamber and inspected to determine whether (cyanoacrylate-coated) fingerprints are present on the substrate. Persons skilled in the art would then process any fingerprints present on the substrate.

### Operation of the Apparatus

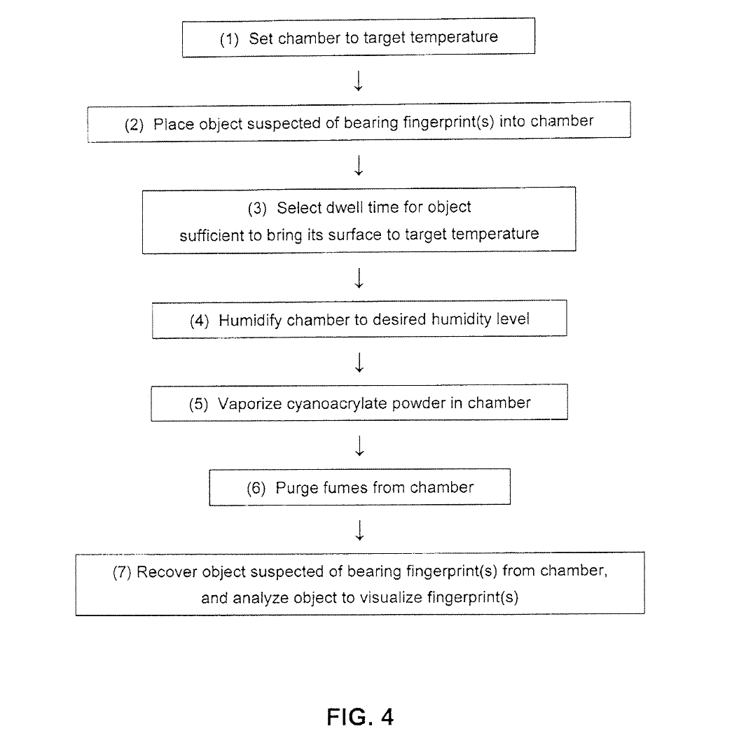

A method of operating the inventive apparatus is outlined in FIG. 4. Step 1 involves setting the chamber to a desired target temperature, typically in the range 35-40° F. In Step 2, the object suspected of bearing fingerprint(s) is placed into chamber. Step 3 entails selecting sufficient dwell time for the object in order to bring its surface to the target temperature. Once the surface of the object has reached the target temperature, Step (4) humidifies the object, with the humidity level in the chamber being raised to a desired target level. Typically a humidity level of about 80% is used, but other levels of humidity may be used if desired, for instance, humidity in the range 75-85% may be appropriate in some instance. If the humidity level is too low, the print will not hydrate. If the humidity level is too high, the substrate may become too wet, and the cyanoacrylate vapor may not adhere to the print or may wipe off the substrate. FIG. 3A schematically illustrates airflow into the chamber during initial stages of processing.

In Step 5, once the desired level of humidity is achieved in the chamber, a cyanoacrylate accelerator, which may be a “hot plate,” is activated. As a first substep in this operation, the user (a) sets a desired operation temperature for the cyanoacrylate accelerator (hot plate) and (b) sets a desired processing time. Appropriate temperatures are typically in the range 100-240° C. Appropriate processing times are typically in the range 15-30 minutes. Airflow within the chamber during processing of the cyanoacrylate is illustrated schematically in FIG. 3B. The chamber box will be fitted with one or more fans 14a, 14b for circulating humidity, temperature, and glue (cyanoacrylate) vapors uniformly throughout the chamber. Typically, more than one such fan may be used to implement expedite the generation of a uniform atmosphere throughout the interior of the chamber. It should be noted that fan icons 14a, 14b in the drawings are not necessarily indicative of the location and/or orientation of specific fans within the apparatus.

The chamber box will also be fitted with a venting system 12, including a purge fan and an air filter (e.g., a carbon filter) to remove glue (cyanoacrylate) vapors from the chamber before the operator opens the door to remove the test substrate from the chamber, thereby avoiding operator exposure to noxious fumes. Once fuming is complete, in Step 6, a filtration unit associated with the apparatus will remove harmful fumes. A typical purge time is approximately 5 minutes. Airflow during the venting/purging process is illustrated schematically in FIG. 3C.

Finally, in Step (7), the object suspected of bearing fingerprint(s) is recovered from the chamber, and the object is analyzed to visualize fingerprint(s) thereon.

The order of steps described above is preferable. However, the order can be changed and/or steps can be added (or possibly deleted) as long as the substrate suspected of bearing a fingerprint is brought into contact with cyanoacrylate fumes under the cooled condition described hereinabove.

The following is a listing of reference characters used in this application:
1 cyanoacrylate fuming chamber
2 substrate suspected of having a fingerprint thereon
3 refrigeration unit
4 location within the chamber for receiving the substrate; shelf
5 nebulizer/humidifier
6 cyanoacrylate powder; cyanoacrylate vapor
7 cyanoacrylate accelerator; hotplate
8 viewing port
10, 10′ hanging rods for receiving substrate
12 purge venting system
14, 14a, 14b internal circulation fans
16 cooling coils
18 interior wall of chamber
20 air filter
22 one-way duct
23 vent to atmosphere
24a communication (illustrated as perforations) between refrigeration module and cooled air supply route within chamber
24b communication (illustrated as perforations) between cooled air supply route within chamber and interior of chamber
25 purge fan

Although specific embodiments of the invention are illustrated and described herein, it will be appreciated by those skilled in the art that a variety of alternate and/or equivalent implementations exist. It should be appreciated that the exemplary embodiment or exemplary embodiments are examples only, and are not intended to limit the scope, applicability, or configuration in any way. Rather, the foregoing summary and detailed description will provide those skilled in the art with a convenient roadmap for implementing at least one exemplary embodiment, it being understood that various changes may be made in the function and arrangement of elements described in an exemplary embodiment without departing from the scope as set forth in the appended claims and their legal equivalents. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, reference numerals are presented for illustrative purposes only and are not intended to limit the scope of the claimed subject matter to the specific examples provided in the present disclosure.

What is claimed is:

1. An apparatus for use in detecting fingerprints, said apparatus comprising:
a chamber suitable for containing a substrate suspected of containing a fingerprint;
a refrigeration unit operatively associated with the chamber;
a nebulizer/humidifier operatively associated with the chamber;
a location within the chamber for receiving the substrate, including a support for a substrate to be tested;
a cyanoacrylate accelerator operatively associated with the chamber, wherein said cyanoacrylate accelerator is capable of heating cyanoacrylate material in the chamber; and
a venting system to purge the atmosphere from the chamber after use, wherein said apparatus does not include heating coils for heating air in or supplied to the chamber or a steam generator for proving moisture in the chamber.

2. The apparatus of claim 1, wherein the chamber ranges in size from 2 feet in height to 2 feet in width to 2 feet in depth to 6 feet in height to 3 feet in depth to 8 feet in width.

3. The apparatus of claim 1, wherein the refrigeration unit is operatively connected with the interior of the chamber via at least one duct and at least one circulation fan.

4. The apparatus of claim 1, wherein a humidifier is located inside of the fingerprint detection chamber.

5. The apparatus of claim 1, wherein the chamber is provided with a foldable shelf and/or with one or more with removable hanging rods.

6. The apparatus of claim 1, wherein the cyanoacrylate accelerator is a hotplate.

7. A method for detecting fingerprints, said method comprising:
providing an apparatus according to claim 1;
setting the temperature of the chamber in said apparatus to a target temperature in the range 1-5° C.;
placing the substrate suspected of containing a fingerprint in the chamber and maintaining the substrate therein for a period of time sufficient to allow the substrate to reach the target temperature;
bringing the humidity within the chamber to a target humidity in the range 75-85% humidity;
providing a cyanoacrylate material in the chamber; and subsequently raising the temperature of the cyanoacrylate material to a temperature which vaporizes the cyanoacrylate material and maintaining a vaporization temperature for 5-45 minutes; then removing the substrate from the chamber and inspecting the substrate to visualize cyanoacrylate-coated fingerprints if present on the substrate.

8. The method of claim 7, wherein said chamber comprises a refrigeration unit operatively connected with the interior of the chamber via a duct, and wherein said apparatus comprises at least one circulation fan to circulate cold air provided by said refrigeration unit.

9. The method of claim 7, wherein said chamber comprises a humidifier located inside of the chamber, a foldable shelf and removable hanging rods for supporting a substrate suspected of containing a fingerprint, and a hotplate.

10. The method of claim 7, wherein the temperature of the chamber in said apparatus is set to a target temperature of 2-4° C.

11. The method of claim 7, wherein bringing the humidity within the chamber is brought to a target humidity of 80% and the substrate suspected of containing a fingerprint is maintained in the chamber for from 15 to 30 minutes.

12. The method of claim 7, wherein the cyanoacrylate material is a powder and the temperature of the cyanoacrylate powder is raised to 220-230° C. and the cyanoacrylate powder is maintained at that temperature for from 15 to 30 minutes.

13. The method of claim 7, further comprising the step of purging the vapors from the interior of the chamber prior to inspecting the substrate to visualize cyanoacrylate-coated fingerprints if present on the substrate.

14. The method of claim 13, wherein said purging is conducted by exhaust fans which pass the fumes in the interior of the chamber through a filtration unit prior to discharging said fumes into the atmosphere.
